(19) United States
(12) Patent Application Publication
(10) Pub. No.: US 2009/0184359 A1
(43) Pub. Date: Jul. 23, 2009

(54) Split-gate non-volatile memory devices having nitride tunneling layers

(76) Inventors: Yue-Song He, San Jose, CA (US); Len Mei, San Jose, CA (US)

Correspondence Address: Haynes and Boone, LLP;IP Section, 2323 Victory Avenue, SUITE 700, Dallas, TX, 75219, US

(21) Appl. No.: 12/017,961

(22) Filed: Jan. 22, 2008

(51) Int. Cl. H01L 21/336; H01L 29/788

(52) U.S. Cl. 257/316; 438/261; 257/E21.422; 257/E29.3

(57) ABSTRACT

A memory device having a cell stack and a select gate formed adjacent to the cell stack. The cell stack includes a first trap-free-nitride layer formed on a channel region of a substrate, a second nitride layer formed on the first nitride layer, an oxide layer formed on the second nitride layer, a control gate formed on the high-K oxide layer, and a poly spacer as the select gate formed adjacent to the control gate.

### TECHNICAL FIELD

The present invention relates to memory devices and, in particular, to split-gate non-volatile memory devices with charge storage regions and nitride tunneling layers.

### BACKGROUND

Some conventional embedded flash memory devices utilize a split gate floating gate device with source side junction Fowler-Nordheim (FN) tunnel erase to provide page erase functionality. By unitizing a select gate transistor, the embedded flash memory cell achieves over erase states without suffering an excess leakage problem during program operation. Compared with conventional stacked gate structure architecture, there is no need to provide a station machine design in the circuitry. Hence, split gate architecture simplifies a circuit design and reduces overall chip size.

However, these flash memory cells have limited scalability. For example, a conventional embedded flash memory cell having a 0.18 um memory cell channel length cannot be scaled due to the source erase option. In general, the source junction needs to be graded enough to improve the post cycling induced read current degradation. Since the source side erase utilizes FN tunneling at the source to gate overlap region, optimizing the source junction profile is necessary for reducing the cycling induced damage to the tunnel oxide to provide a certain read current value for post program/erase cycled part. In some cases, if the device source junction is more graded, the read current reduction is smaller compared with an abrupt source junction.

However, to make the source junction more graded, junction depth is exaggerated, and the graded source junction in conventional memory devices takes a large portion of the channel region area. Thus, the memory cell may be easily punched through. To prevent punch-through of the memory device, the channel length is enlarged, and the cell cannot be scaled accordingly. Moreover, the cell size is not small enough to be competitive in many flash memory devices, and the application is limited.

### SUMMARY

The present disclosure overcomes the deficiencies of conventional memory devices by providing a scalable memory device having a smaller cell size of at least less than 180 nm. In various embodiments, cell size refers to the area of the memory cell device, and the 0.18 um comprises the device channel length of the channel region. In one embodiment, the scalable memory cell of the present disclosure may be sized to approximately 90 nm. The present disclosure describes a split-gate silicon-rich-nitride based non-volatile memory device, such as a SG-MANNS (split-gate metal/aluminum-oxide/silicon-rich-nitride/trap-free-nitride/silicon) memory cell for low voltage high speed embedded memory applications.

In various implementations, the SG-MANNS cell provides low operating voltages, fast read and writes times, and smaller cell size. In one aspect, a thick trap-free--nitride layer utilized as a tunneling layer provides improved data retention.

Embodiments of the present disclosure provide for a program operation for fast write speed, such as, for example, source side hot carrier injection (i.e., hot electron injection), which allows for fast write speed. Embodiments of the present disclosure provide for an erase operation, such as, for example, use of trap-free-nitride as a tunneling layer to lower hole barrier height existing in the nitride material, which allows for smaller cell size and lower operating voltage.

Embodiments of the present disclosure provide a non-volatile memory device having a cell stack and a select gate formed adjacent to a sidewall of the cell stack. The cell stack includes a first trap-free-nitride layer formed on a channel region of a substrate, a second nitride layer that functions as charge storage region formed on the first nitride layer, a high dielectric (i.e., high K) constant oxide layer (e.g., Al₂O₃) formed on the second nitride layer, and a control gate formed on the oxide layer. In one aspect, when a selected bias of a first polarity is applied to the control gate and the select gate, charges of an opposite polarity are injected from the channel region through the first trap-free-nitride layer and into the second nitride layer to store charges of the opposite polarity in second nitride layer. In another aspect, when a selected bias of a second polarity opposite to the first polarity is applied to the control gate, charges of the first polarity are tunneled from the channel region through the first nitride layer and into the second nitride layer to store charges of the first polarity in second nitride layer.

In one implementation, the first polarity comprises a positive polarity and the second polarity comprises a negative polarity. In another implementation, the first trap-free-nitride layer comprises silicon-nitride (SiN) and functions as a tunneling dielectric layer, the second nitride layer comprises silicon-rich-nitride (Si₃N₄) and functions as a charge storage layer, and the oxide layer comprises high dielectric constant aluminum-oxide (Al₂O₃) and functions as a blocking dielectric layer.

Embodiments of the present disclosure provide a method for manufacturing a non-volatile memory device. The method includes forming a first nitride layer on a channel region of a substrate, forming a second nitride layer on the first nitride layer, forming an oxide layer on the second nitride layer, forming a control gate on the oxide layer, and forming a select gate adjacent to the second nitride layer. In one aspect, applying a selected bias of a first polarity to the control gate and the select gate stores charges of an opposite polarity in the second nitride layer. In another aspect, applying a selected bias of a second polarity opposite to the first polarity to the control gate stores charges of the first polarity in the second nitride layer.

In one implementation, the first polarity comprises a positive polarity and the second polarity comprises a negative polarity. In another implementation, the first nitride layer functions as a tunneling dielectric layer and comprises silicon-nitride (SiN), the second nitride layer functions as a charge storage layer and comprises silicon-rich-nitride (Si₃N₄), and the oxide layer functions as a blocking dielectric layer and comprises aluminum-oxide (Al₂O₃).

The scope of the disclosure is defined by the claims, which are incorporated into this section by reference. A more complete understanding of embodiments will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIGS. 1A-1L show a process for forming a non-volatile memory device in accordance with one embodiment of the present disclosure.

FIG. 2 shows one embodiment of a program operation for the non-volatile memory device formed from the process of FIGS. 1A-1L.

FIG. 3 shows one embodiment of an erase operation for the non-volatile memory device formed from the process of FIGS. 1A-1L.

Embodiments and their advantages are best understood by referring to the detailed description that follows. It should be appreciated that like reference numerals are used to identify like elements illustrated in one or more of the figures.

### DETAILED DESCRIPTION

The present disclosure describes a split-gate trap-free-nitride based non-volatile memory device, such as a SG-MANNS memory cell for embedded flash memory applications. In various implementations, the SG-MANNS cell provides low operating voltages, fast read and writes times, smaller cell size and improved data retention.

The memory cell of the present disclosure allows for lower program and erase voltages. With a channel erase approach, a smaller memory cell size is achievable, and due to faster access times, a high voltage peripheral P-channel device with breakdown voltage up to 18V is not needed. The memory cell of the present disclosure is compatible with existing CMOS (complementary metal oxide semiconductor) processes thereby allowing for lower wafer costs, lower test costs, and relatively good reliability. The use of a thick nitride layer as a tunneling layer provides improved data retention.

Embodiments of the present disclosure provide for a program operation for fast write speed, such as, for example, source side hot carrier injection (i.e., hot electron injection), which allows for fast write speed. Embodiments of the present disclosure provide for an erase operation, such as, for example, Fowler-Nordheim (FN) tunneling through a trap-free-nitride layer that has lower hole barrier height, which allows for smaller cell size and lower operation voltage. Embodiments of the present disclosure provide a scalable memory cell having a cell channel length of at least less than 180 nm. For example, in one embodiment, the cell channel length of the scalable memory cell may be sized to approximately 90 nm. These and other aspects of the present disclosure will be discussed in greater detail herein.

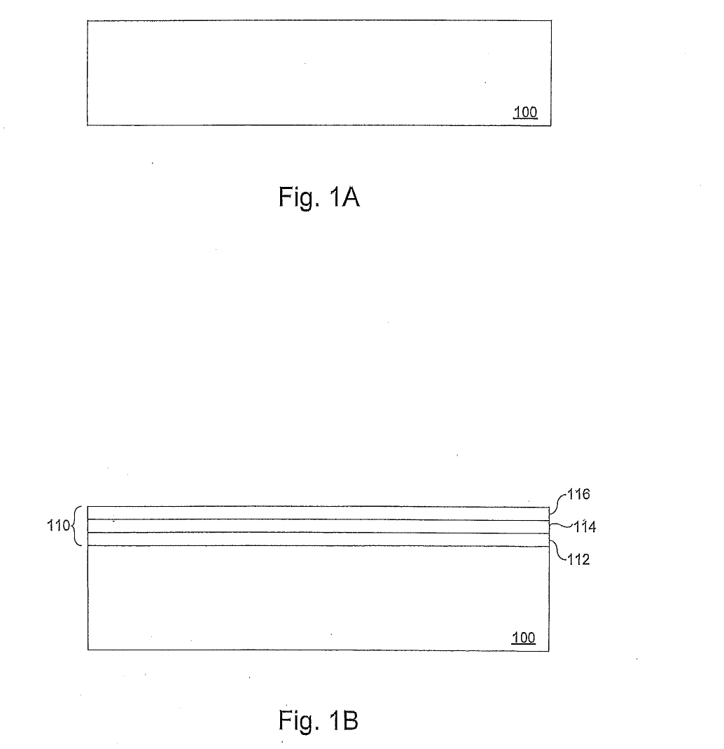

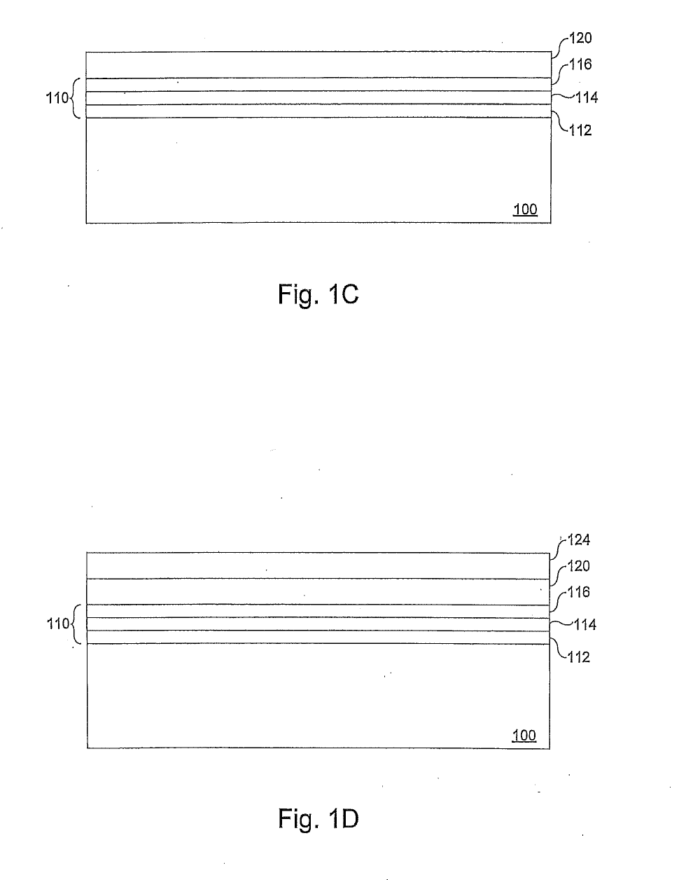

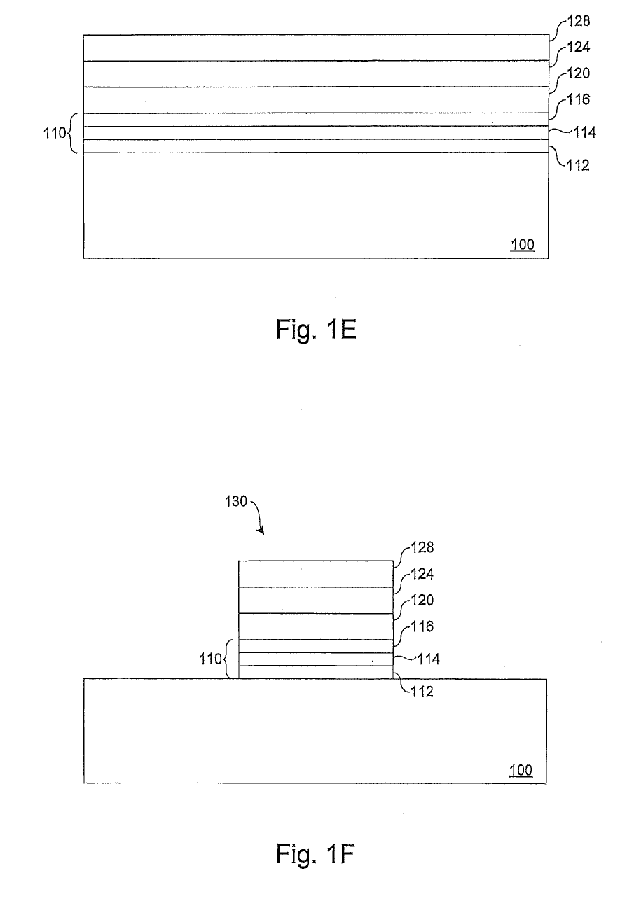

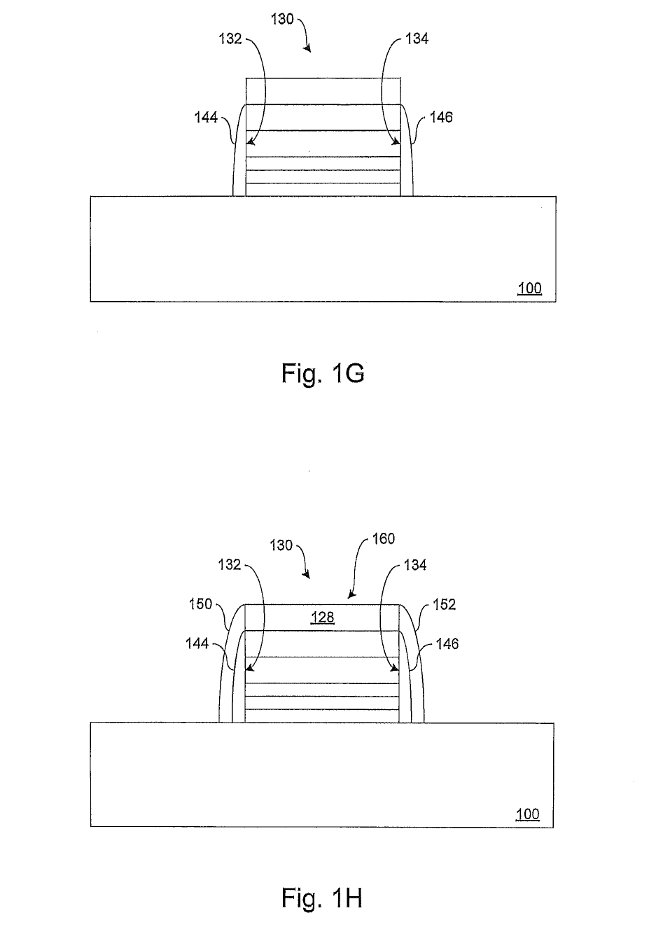

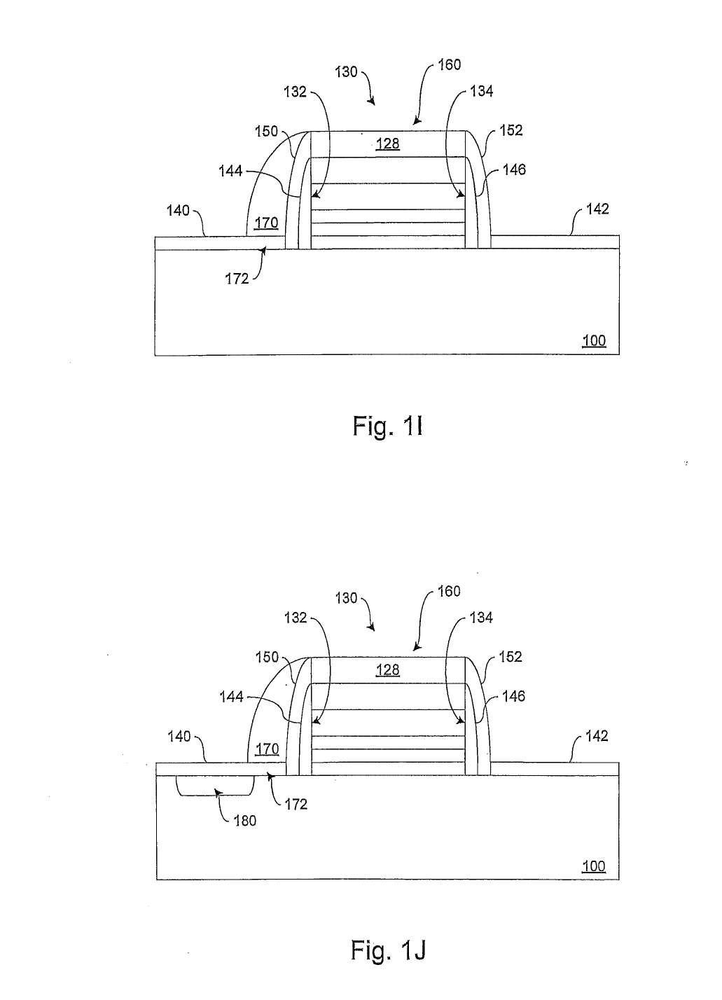

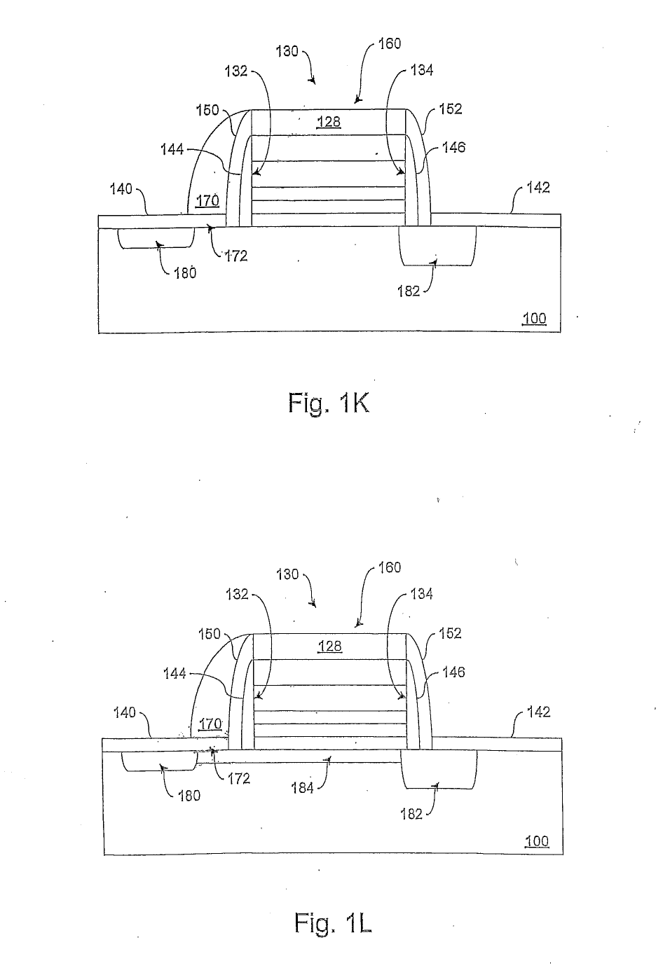

FIGS. 1A-1L show one embodiment of a process for forming a memory cell of the present disclosure. In one embodiment, the memory cell comprises a non-volatile SG-MANNS memory cell for flash memory applications having a trap-free-nitride layer as a tunneling layer and silicon-rich-nitride layer that functions as a charge storage region.

FIG. 1A shows one embodiment of a substrate 100 comprising a semiconductor material. In one implementation, substrate 100 comprises a P-type mono-crystalline silicon (Si) substrate having, in one example, a dopant concentration of approximately 5e14˜1e15/cm3.

FIG. 1B shows one embodiment of forming an ONN (oxide-nitride-nitride) layer 110 on substrate 100. In one implementation, ONN layer 110 includes a first nitride layer 112, a second nitride layer 114 and an oxide layer 116.

In one embodiment, first nitride layer 112 comprises a trap-free-nitride layer of silicon-nitride (SiN) formed on substrate 100 and functions as a tunneling dielectric region. In one implementation, first nitride layer 112 may be formed with a thickness of approximately 25-45 A (Angstrom). In another implementation, first nitride layer 112 may be formed with a thickness of approximately 35 A. In one embodiment, the trap-free--nitride layer may be formed by a vapor jet deposition technique.

In one embodiment, second nitride layer 114 is formed on first nitride layer 112 and comprises a charge storage region of a silicon-rich-nitride material, such as, for example, silicon-nitride (Si₃N₄). In one implementation, second nitride layer 114 may be formed with a thickness of approximately 50-70 A. In another implementation, second nitride layer 114 may be form with a thickness of approximately 60 A.

In one embodiment, oxide layer 116 comprises a high-K dielectric material of aluminum-oxide (Al₂O₃) formed on second nitride layer 114 and functions as a blocking dielectric region. In one implementation, oxide layer 116 may be formed with a thickness of approximately 70-90 A. In another implementation, oxide layer 116 may be formed with a thickness of approximately 80 A.

FIG. 1C shows one embodiment of forming a first gate layer 120 on oxide layer 116 of ONN layer 110. In one implementation, first gate layer 120 comprises a gate of poly-silicon (poly-Si). In another implementation, first gate layer 120 comprises a gate of aluminum (Al). In various other implementations, first gate layer 120 may comprise a gate of poly-silicon (poly-Si) and/or doped poly-Si (doped n+ or p+ poly-Si). In one implementation, first gate layer 120 may be formed with a thickness of approximately 800˜1200 A. In another implementation, first gate layer 120 may be formed with a thickness of approximately 1000 A.

FIG. 1D shows one embodiment of forming a second gate layer 124 on first gate layer 120. In various implementations, second gate layer 124 may be referred to as an electrode layer comprising tungsten silicide with thickness of 1000 A.

In one embodiment, tunneling dielectric region (i.e., first nitride layer 112) is formed between charge storage region (i.e., second nitride layer 114) and substrate 100 as a tunnel dielectric and also to reduce charge leakage from the charge storage region (i.e., 114) to substrate 100. Blocking dielectric region (i.e., oxide layer 116) is formed between charge storage region (i.e., 114) and gate (i.e., gate layer 120) to reduce charge leakage from the charge storage region (i.e., 114) to gate (i.e., 120). In various implementations, first and second gate layers 120, 124 form a split gate, which may be referred to as a control gate.

FIG. 1E shows one embodiment of forming a protection layer 128 on electrode layer 124. In one implementation, protection layer 128 comprises a region of silicon-nitride (SiN). It should be appreciated that protection layer 128 may be referred to as a hard mask without departing from the scope of the present disclosure.

FIG. 1F shows one embodiment of etching a portion of layers 110 (i.e., 112, 114, 116), 120, 124, 128 to form a cell stack 130 on substrate 100. It should be appreciated that various types of generally known etching techniques may be used without departing from the scope of the present disclosure.

FIG. 1G shows one embodiment of forming oxide sidewall portions 144, 146 on substrate 100 and sidewalls 132, 134 of cell stack 130. As shown in FIG. 1G, cell stack 130 comprises first and second sidewalls 132, 134 that extend vertically from substrate 100. As further shown in FIG. 1G, first and second sidewall portions 144, 146 are formed on first and second sidewalls 132, 134 of cell stack 130, respectively, so as to extend vertically adjacent thereto. In one embodiment, the sidewalls 144, 146 are formed with deposition of a high temperature oxide (HTO) (e.g., 60˜100 Å) followed with a spacer etch. In one implementation, each sidewall portion 144, 146 comprises a layer of oxide (e.g., silicon dioxide: SiO₂) that insulates and/or isolates end portions of layers 112, 114, 116, 120, 124 from other layers including substrate 100 to reduce charge leakage.

FIG. 1H shows one embodiment of forming spacers 150, 152 on substrate 100 and on sidewall portions 144, 146. As shown in FIG. 1H, first and second spacers 150, 152 are formed adjacent to first and second sidewalls 132, 134 of cell stack 130, respectively, with sidewall portions 144, 146 interposed therebetween. Spacers 150, 152 comprise silicon-nitride (SiN), which is similar to protection layer 128. As further shown in FIG. 1H, an upper portion of each spacer 150, 152 contacts end portions of protection layer 128, respectively, to form a cap 160 over cell stack 130. In one implementation, cap 160 comprises a series combination of SiN components including first spacer 150, protection layer 128 and second spacer 152.

FIG. 1I shows one embodiment of forming oxide layers 140, 142 on substrate 100 and adjacent to sidewall portions 144, 146, respectively. As further shown in FIG. 1I, a select gate 170 is formed on oxide layer 140 and adjacent to first spacer 150. In one implementation, oxide layers 140, 142 comprise silicon-dioxide (SiO₂) and select gate 170 comprises poly-silicon (poly-Si). As further shown in FIG. 1I, select gate 170 may be formed adjacent to first sidewall 132 of cell stack 130 with first spacer 150 and first sidewall portion 144 interposed therebetween. In various implementations, select gate 170 may be referred to as a word line.

As shown in FIG. 1I, a portion of oxide layer 140 is interposed between select gate 170 and substrate 100. Hence, in one aspect, at least a portion of oxide layer 140 may be referred to as a select gate oxide 172. In one implementation, select gate oxide 172 may be formed with a thickness of approximately 80-200 A. In another implementation, select gate oxide 172 may be formed with a thickness of approximately 100-150 A. In still another implementation, select gate oxide 172 may be formed with a thickness of approximately 120 A.

FIG. 1J shows one embodiment of forming a drain region 180 in substrate 100. In one implementation, drain region 180 is formed by implanting (n+) dopant in the area of drain region 180 of substrate 100. In one implementation, drain region 180 is formed in substrate 100 below oxide layer 140 and adjacent to select gate 170.

FIG. 1K shows one embodiment of forming a source region 182 in substrate 100. In one implementation, source region 182 is formed by implanting (n+) dopant in the area of source region 182 of substrate 100. In one implementation, source region 182 is formed in substrate 100 below oxide layer 142.

FIG. 1L shows one embodiment of forming a channel region 184 in substrate 100. In one implementation, channel region 184 comprises a P-type channel region that is formed adjacent first nitride layer 112 of cell stack 130 and interposed between drain region 180 and source region 182. In other words, as shown in FIG. 1L, P-type channel region 184 is formed in substrate 100 between N-type drain and source regions 180, 182, and charge storage region (i.e., nitride layer 114) overlies channel region 184.

It should be appreciated that, in one aspect, channel region 184 may comprise a portion of P-type well formed in substrate 100 and may be isolated from other portions of substrate 100 by PN junctions and/or dielectric regions. In another aspect, tunnel dielectric region (i.e., first nitride layer 112) may be formed on channel region 184 so as to overlap or overlie at least a portion of drain and source regions 180, 182. It should be appreciated that, in various embodiments, channel region 184 may be formed at any appropriate time during the process as discussed in reference to FIGS. 1A-1L.

It should be appreciated that, in various embodiments, the dopant concentrations of the drain region, the source region, and the channel region may vary depending on the particular implementation. In one embodiment, the dopant concentration of the drain region may be approximately 5e18˜5e19/cm3, the dopant concentration of the source region may be approximately 5e18˜5e19/cm3, and the dopant concentration of the channel region may be approximately 2e17˜1e18/cm3.

The fabrication process discussed in reference to FIGS. 1A-1L should not limit the present disclosure. In various implementations, any one or more of layers 112, 114, 116, 120, 124, 128, 140, 142, 150, 152, 170 may be patterned using a separate mask, and the P and N conductivity types may be reversed. The present disclosure should not be limited to any particular cell geometry. In various implementations, all or part of channel region 184 may be vertical, and all or part of charge storage region (i.e., nitride layer 114) may be formed in a trench (not shown) in substrate 100. The memory cell stack 130 may comprise a multi-level cell with the charge storage region (i.e., nitride layer 114) divided into sub-regions each of which may store one bit of information. The present disclosure should not be limited to particular materials except as defined by the claims.

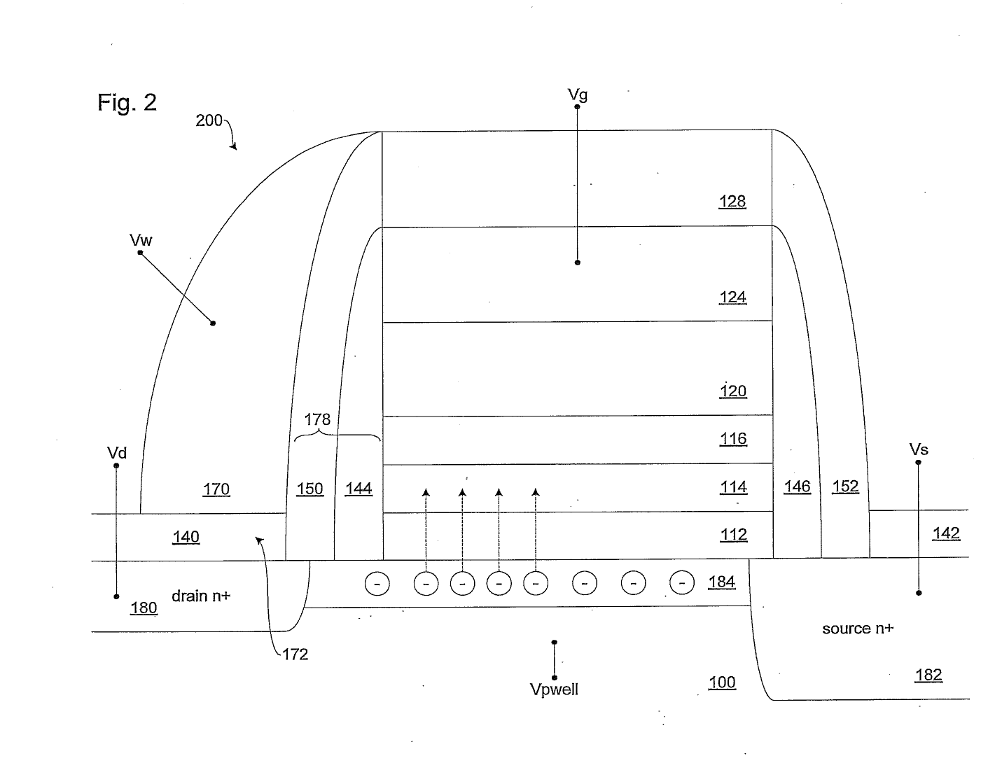

FIG. 2 shows one embodiment of a program operation for SG-MANNS memory cell 200 formed from the process of FIGS. 1A-1L. In one implementation, the program operation shown in FIG. 2 may be referred to as channel hot electron injection of electrons from channel region 184 to second nitride layer 114. In one embodiment, a positive bias is applied to gate region 124 and source region 182 to inject electrons into second nitride layer 114 at the gap 178 between gate region 124 and select gate 170. As shown in FIG. 2, the gap 178 may comprise the vertical region defined by sidewall portion 144 and first spacer 150 between gates 124, 170. In one aspect, second nitride layer 114 functions as a charge storage layer or region for storing or trapping negative charges.

In one implementation, when voltages are applied to gate region 124 (e.g., Vg of approx. +5-9V and, in one instance, approx. +6.5V), source region 182 (e.g., Vs of approx. +4.5-6.5V and, in one instance, approx. +5V), and drain region 180 (e.g., Vd of approx. 0V) relative to channel region 184, some electrons in channel region 184 gain enough energy to tunnel through dielectric region (i.e., first nitride layer 112) into the charge storage region (i.e., second nitride layer 114). In one example, electrons become trapped in the charge storage region thereby increasing the threshold voltage of the memory cell 200, which may be referred to as a program state or “0” state.

In one embodiment, the threshold voltage (Vt) may be sensed by sensing the current between drain and source regions 180, 182 when suitable voltages are applied to gate region 124, substrate 100, and drain and source regions 180, 182. In another embodiment, when a negative voltage is applied to gate region 124 relative to channel region 184 or drain and source regions 180, 182, the threshold voltage (Vt) of the memory cell 200 drops, which may be referred to as an erase state or “1” state.

The following table describes one embodiment of the approximate node voltages for programming SG-MANNS memory cell 200 of FIG. 2:

Program Voltage Table

| | Range | Approx. |
|---|---|---|
| Vg | +5 to +9 V | +6.5 V |
| Vd | ~0 V | 0 V |
| Vs | +4.5 to +6.5 V | +5.0 V |
| Vw | +0.8 to +2 V | +1.2 V |
| Vpwell | ~0 V | 0 V |

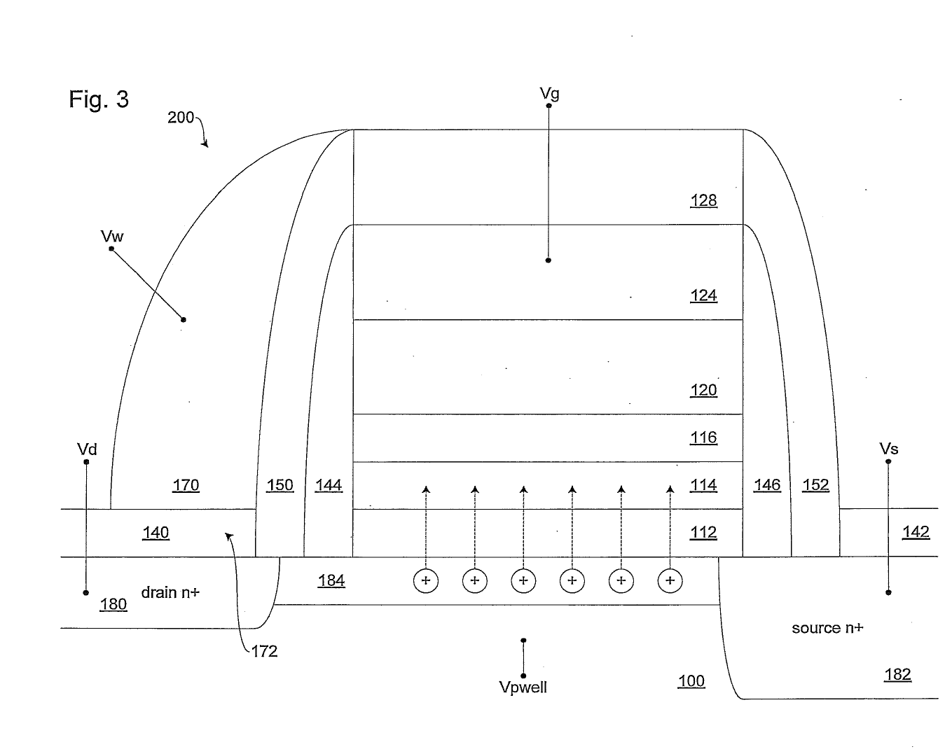

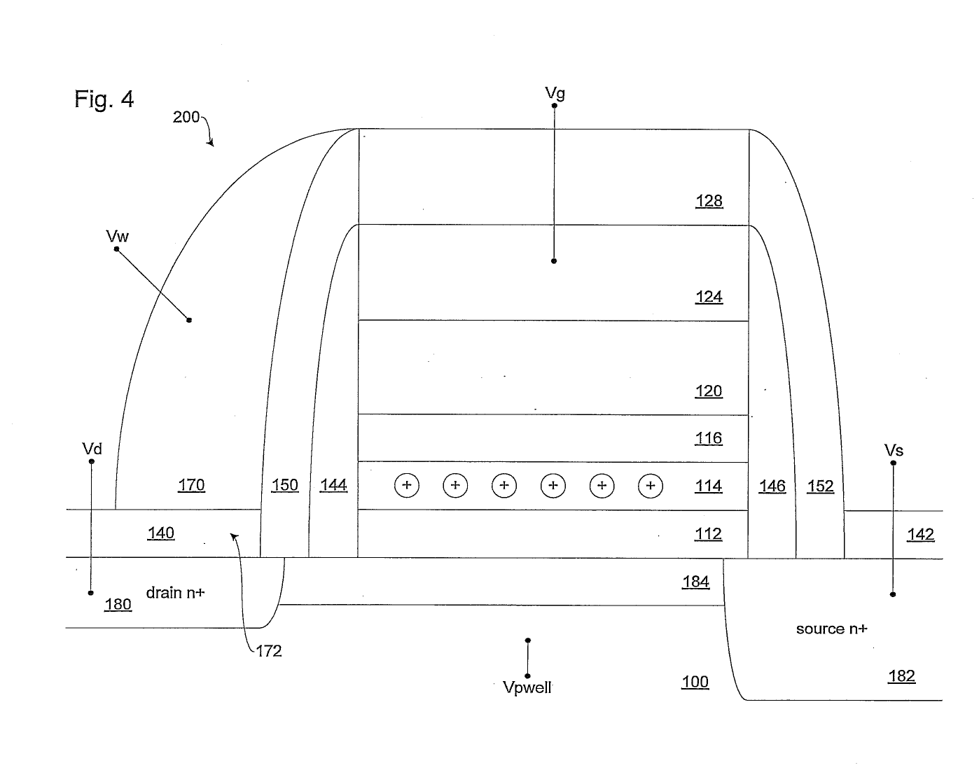

FIG. 3 shows one embodiment of an erase operation for SG-MANNS memory cell 200 formed from the process of FIGS. 1A-1L. In one implementation, the erase operation shown in FIG. 3 may be referred to as FN tunneling of holes from channel region 184 to second nitride layer 114. As described herein, a negative bias is applied to gate region 124 (e.g., Vg of approx. −3V) and a positive bias is applied to Vpwell region of substrate 100 (e.g., Vpwell of approx. +7V) to inject holes into second nitride layer 114 from channel region 184 of substrate 100. In one embodiment, second nitride layer 114 functions as a charge storage layer or region for storing or trapping positive charges.

In one implementation, when a negative bias is applied to the gate region 124, FN tunneling occurs so as to inject holes from channel region 184 of substrate 100 to charge storage region 114 due to a lower hole barrier (e.g., 1.9 eV) of SiN than that of a typical silicon-oxide (SiO) (e.g., 4.5 eV). Hence, with use of SiN as the tunneling dielectric in first nitride layer 112, the erase voltage may be greatly reduced.

The following table describes one embodiment of the approximate node voltages for erasing SG-MANNS memory cell 200 of FIG. 3:

Erase Voltage Table

| | Range | Approx. |
|---|---|---|
| Vg | −3 to −4 V | −3 V |
| Vd | Float | Float |
| Vs | Float | Float |
| Vw | Float | Float |
| Vpwell | +7 to +8 V | +7 V |

In one implementation, to program SG-MANNS memory cell 200 using channel hot electron injection, a voltage difference is created between drain and source regions 180, 182, and gate region 124 is driven to a positive voltage relative to channel region 184 for inversion of channel region 184 from type P to type N. As such, current flows between drain and source regions 180, 182 through channel region 184 to inject hot electrons from channel region 184 of substrate 100 to charge storage region (i.e., second nitride layer 114). These hot electrons pass through tunneling dielectric region (i.e., first nitride layer 112) to the charge storage region. As previously discussed, these hot injected electrons become trapped in the charge storage region (i.e., second nitride layer 114), thereby changing the threshold voltage of the channel region 184 in SG-MANNS memory cell 200. In another implementation, SG-MANNS memory cell 200 may be erased by driving the gate region 124 to a negative voltage relative to channel region 128 and/or one or both of drain and source regions 180, 182.

FIG. 4 shows one embodiment of a read operation for SG-MANNS memory cell 200 formed from the process of FIGS. 1A-1L. In one implementation, as previously described, second nitride layer 114 functions as a charge storage layer or region for storing or trapping positive charges, and the read operation shown in FIG. 4 shows holes trapped in second nitride layer 114. For the read operation, a positive bias is applied to drain region 180 (e.g., Vg of approx. +1V) and a zero voltage bias is applied to source region 182 of substrate 100 (e.g., Vs of approx. 0V) and Vpwell region of substrate 100 (e.g., Vpwell of approx. 0V) to measure a voltage difference between the layers.

The following table describes one embodiment of the approximate node voltages for reading SG-MANNS memory cell 200 of FIG. 4:

Read Voltage Table

| | Range | Approx. |
|---|---|---|
| Vg | Vcc | Vcc |
| Vd | +1 V | +1 V |
| Vs | 0 V | 0 V |
| Vw | Vcc | Vcc |
| Vpwell | 0 V | 0 V |

The following table summarizes the various embodiments of approximate node voltages for the programming, erasing and reading of SG-MANNS memory cell 200 of the present disclosure for selected and unselected cells:

Selected Cell

| | Vg | Vwl | Vpw | Vs | Vd |
|---|---|---|---|---|---|
| Program | +6.5 V | +1.2 V | 0 V | +5 V | 0 V |
| Erase | −3 V | Float | +7 V | Float | Float |
| Read | Vcc | Vcc | 0 V | 0 V | +1 V |

Unselected Cell

| | Vg | Vwl | Vpw | Vs | Vd |
|---|---|---|---|---|---|
| Program | +6.5 V | +1.2 V | 0 V | +5 V | >2.5 V |
| | +6.5 V | −1 V | 0 V | +5 V | >2.5 V/0 V |
| | 0 V | 0 V | 0 V | 0 V | >2.5 V/0 V |
| Erase | Vcc+ | Vcc+ | +7 V | Float | Float |
| Read | — | — | — | — | 0 V |

In one embodiment, during the erase operation, the unselected cell may be biased at Vcc (or higher with a desirable instance of Pwell bias) to inhibit an erase induced program cell disturb.

Embodiments of the present disclosure provide a novel SG-MANNS memory cell structure and operation scheme for embedded flash memory applications. Compared with conventional split gate source side erase (SSE) cells, the proposed cell architecture and operation scheme has the following advantages. Tunneling through a low barrier height of Nitride material enables a lower operation voltage, and source side hot carrier injection provides a faster write speed. Because of thicker bottom Nitride as compared with conventional SONOS thin bottom oxide (e.g., 21 Å), the proposed memory cell structure provides improved data retention over conventional SONOS structures. Because of the channel erase approach, a large source junction to gate overlap is unnecessary, and the cell size is smaller as compared with conventional SSE split gate cells. Therefore, the proposed cell structure provides an improved embedded flash memory application.

Embodiments described herein illustrate but do not limit the disclosure. It should be understood that numerous modifications and variations are possible in accordance with the principles of the disclosure. Accordingly, the scope and spirit of the disclosure should be defined by the following claims.

We claim:

1. A device for non-volatile memory, the device comprising:
a cell stack comprising:
a first nitride layer formed on a channel region of a substrate;
a second nitride layer formed on the first nitride layer;
an oxide layer formed on the second nitride layer; and
a control gate formed on the oxide layer;
a select gate formed adjacent to a first sidewall of the cell stack,
wherein, when a selected bias of a first polarity is applied to the control gate and the select gate, charges of an opposite polarity are injected from the channel region of the substrate through the first nitride layer and into the second nitride layer to thereby store the charges of the opposite polarity in the second nitride layer, and
wherein, when a selected bias of a second polarity opposite to the first polarity is applied to the control gate, charges of the first polarity are tunneled from the channel region of the substrate through the first nitride layer and into the second nitride layer to thereby store the charges of the first polarity in the second nitride layer.

2. The device of claim 1, wherein the first polarity comprises a positive polarity and the second polarity comprises a negative polarity.

3. The device of claim 1, wherein the substrate comprises a P-type mono-crystalline silicon (Si) substrate.

4. The device of claim 1, wherein the first nitride layer comprises a trap-free-nitride layer of silicon-nitride (SiN) and functions as a tunneling dielectric layer.

5. The device of claim 1, wherein the first nitride layer comprises silicon-nitride (SiN) having a thickness of approximately 35 A.

6. The device of claim 1, wherein the second nitride layer comprises silicon-rich-nitride (Si₃N₄) and functions as a charge storage layer.

7. The device of claim 1, wherein the second nitride layer comprises silicon-rich-nitride (Si₃N₄) having a thickness of approximately 60 A.

8. The device of claim 1, wherein the oxide layer comprises a high-K dielectric layer of aluminum-oxide (Al₂O₃) and functions as a blocking dielectric layer.

9. The device of claim 1, wherein the oxide layer comprises aluminum-oxide (Al₂O₃) having a thickness of approximately 80 A.

10. The device of claim 1, wherein the control gate comprises a first gate layer positioned adjacent to the oxide layer, and wherein the first gate layer comprises at least one of poly-silicon (poly-Si), doped poly-Si, aluminum (Al), phosphorous (P), tungsten (W) and tantalum (Ta).

11. The device of claim 1, wherein the control gate comprises a second gate layer positioned adjacent to the first gate layer, and wherein the second gate layer comprises at least one of poly-silicon (poly-Si) and aluminum (Al).

12. The device of claim 1, further comprising a protection layer formed on the control gate, wherein the protection layer comprises silicon-nitride (SiN).

13. The device of claim 1, wherein the first nitride layer, second nitride layer, oxide layer and control gate form a memory cell on the substrate.

14. The device of claim 1, further comprising first, second and third oxide regions, wherein the first oxide region is formed between the first sidewall of the cell stack and the select gate, and wherein the second oxide region is formed adjacent to a second sidewall of the cell stack, and wherein the third oxide region is formed between the select gate and the substrate.

15. The device of claim 14, further comprising first and second spacers, wherein the first spacer is formed between the first oxide region and the select gate, and wherein the second spacer is formed adjacent to the second oxide region, and wherein the first and second spacers comprise silicon-nitride (SiN).

16. The device of claim 1, wherein the select gate comprises poly-silicon (poly-Si) having a thickness of approximately 80-200 A.

17. The device of claim 1, wherein the select gate comprises poly-silicon (poly-Si) having a thickness of approximately 120 A.

18. The device of claim 1, further comprising a drain region and a source region formed in the substrate, wherein the drain region is formed adjacent to the select gate, and wherein the source region is formed adjacent to the cell stack opposite the drain region, and wherein the channel region is formed between the drain and source regions.

19. A method for manufacturing a non-volatile memory device, the method comprising:
forming a first nitride layer on a channel region of a substrate;
forming a second nitride layer on the first nitride layer;
forming an oxide layer on the second nitride layer;
forming a control gate on the oxide layer; and
forming a select gate adjacent to the second nitride layer,
wherein applying a selected bias of a first polarity to the control gate and the select gate stores charges of an opposite polarity in the second nitride layer, and
wherein applying a selected bias of a second polarity opposite the first polarity to the control gate stores charges of the first polarity in the second nitride layer.

20. The device of claim 19, wherein the first polarity comprises a positive polarity and the second polarity comprises a negative polarity.

21. The method of claim 19, wherein applying a positive bias to the control gate and the select gate causes negative charges to be injected from the channel region of the substrate through the first nitride layer and into the second nitride layer for storage of the negative charges in the second nitride layer.

22. The method of claim 19, wherein applying a negative bias to the control gate causes positive charges to be tunneled from the channel region of the substrate through the first nitride layer and into the second nitride layer for storage of the positive charges in the second nitride layer.

23. The method of claim 19, wherein the first nitride layer comprises trap-free-nitride layer of silicon-nitride (SiN) and functions as a tunneling dielectric layer.

24. The method of claim 19, wherein the second nitride layer functions as a charge storage layer and comprises silicon-rich-nitride (Si₃N₄).

25. The method of claim 19, wherein the oxide layer functions as a blocking dielectric layer and comprises a high-K dielectric material of aluminum-oxide (Al₂O₃).
